(19) United States
(12) Patent Application Publication
(10) Pub. No.: US 2025/0264791 A1
(43) Pub. Date: Aug. 21, 2025

(54) PHOTOMASK PATTERN

(71) Applicant: Winbond Electronics Corp., Taichung City (TW)

(72) Inventors: Ching-Chun HUANG, Taichung City (TW); Kun-Che WU, Taichung City (TW); Tsung-Wei LIN, Taichung City (TW)

(21) Appl. No.: 18/935,025

(22) Filed: Nov. 1, 2024

(30) Foreign Application Priority Data
Feb. 20, 2024 (TW) 113105976

(51) Int. Cl. G03F 1/00

(52) U.S. Cl. CPC G03F 1/00

(57) ABSTRACT

A photomask pattern is provided. The photomask pattern includes a central region and a peripheral region surrounding the central region. The photomask pattern further includes a plurality of striped patterns disposed in the central region and the peripheral region. The striped patterns extend in a first direction and are aligned in a second direction, and the first direction intersects the second direction. In a top view, the sidewalls of each of the striped patterns include a straight sidewall extending in the first direction in the central region. In the top view, the sidewalls of each of the striped patterns include a stepped sidewall extending in the first direction in the peripheral region.

### CROSS REFERENCE TO RELATED APPLICATIONS

This Application claims priority of Taiwan Patent Application No. 113105976 filed on Feb. 20, 2024, the entirety of which is incorporated by reference herein.

### BACKGROUND OF THE INVENTION

### Field of the Invention

The present disclosure relates to a semiconductor process technology, and in particular to photomask patterns with a hybrid design of stepped sidewalls and straight sidewalls.

### Description of the Related Art

The critical dimensions of memory elements are gradually being scaled down as development of those memory elements advances, and the resistances of lithography processing and etching are gradually increasing. In a conventional semiconductor process, the lithography process is an important step in transferring the layout of an integrated circuit to a semiconductor chip. Generally, the photomask layout is designed based on the integrated circuit layout, and then the photomask manufacturers form the photomask layout on the photomask. The photomask pattern is then transferred to the photoresist layer on the surface of the semiconductor chip in equal proportions during the lithography process, and exposure and other related steps are performed to complete the lithography process. However, as the critical dimension of the memory device scales down, the design of the layout pattern of the photomask is generally further improved by optical proximity correction (OPC) to improve the exposure problems may be encountered. Corrections to the layout pattern of the photomask may adversely increase the processing progress by increasing the manufacturing time for the photomask manufacturers.

Therefore, the industry still needs to improve the related photomask patterns to achieve the desired goal of maintaining the memory device yield and manufacturing progress.

### BRIEF SUMMARY OF THE INVENTION

The embodiment of the present disclosure provides photomask patterns with hybrid stepped sidewalls and straight sidewalls, thereby improving the edge roughness of the subsequent photoresist layer after the exposure, and reducing the manufacturing time of the related photomask set.

An embodiment of the present disclosure provides a photomask pattern. The photomask pattern includes a central region and a peripheral region surrounding the central region. The photomask pattern further includes a plurality of striped patterns disposed in the central region and the peripheral region. The striped patterns extend in a first direction and are aligned in a second direction, and the first direction intersects the second direction. In a top view, the sidewalls of each of the striped patterns include a straight sidewall extending in the first direction in the central region. In the top view, the sidewalls of each of the striped patterns include a stepped sidewall extending in the first direction in the peripheral region.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a top view of the photomask pattern 10, in accordance with some embodiments of the present disclosure;

FIG. 2 illustrates a fragmentary top view of the photomask pattern 10 in the region 200 of FIG. 1, in accordance with some embodiments of the present disclosure;

FIG. 3 illustrates a fragmentary top view of the photomask pattern 10 in the region 300 of FIG. 2, in accordance with some embodiments of the present disclosure;

FIG. 4 illustrates a fragmentary top view of the photomask pattern 10 in the region 400 of FIG. 1, in accordance with some embodiments of the present disclosure;

FIG. 5 illustrates a fragmentary top view of the photomask pattern 10 in the region 500 of FIG. 3, in accordance with some embodiments of the present disclosure;

FIG. 6 illustrates a fragmentary top view of the photomask pattern 10 in the region 500 of FIG. 3, in accordance with some other embodiments of the present disclosure.

### DETAILED DESCRIPTION OF THE INVENTION

The following disclosure provides many different embodiments, or examples, the term “about” as used herein indicates the value of a given quantity that can vary based on a particular technology node associated with the subject semiconductor device. In some embodiments, based on the particular technology node, the term “about” can indicate a value of a given quantity that varies within, for example, 10-30% of the value (e.g., ±10%, ±20%, or ±30% of the value).

Generally, the manufacturing steps of the semiconductor devices may include, for example, photomask design, photomask manufacturing by the photomask manufacturer, and product manufacturing by the integrated circuit manufacturer/fabricator. The photomask design may generate a layout pattern of the semiconductor device, such as a layout pattern of a metallic layer, a dielectric layer, or a semiconductor layer of the semiconductor device, and the layout patterns of these different layers may be assembled into various components of the semiconductor device. For example, these patterns may later be formed into active regions, gate structures, source/drain structures, or bonding pads, or the like, in a memory device.

In one embodiment, the layout pattern design of the photomask includes consideration of optical proximity correction (OPC), which is the use of lithography enhancement techniques to compensate for image distortions that may be caused, for example, by diffraction, interference, or other optical effects. In one embodiment, the layout pattern design of the photomask further includes resolution enhancement techniques such as off-axis illumination, sub-resolution assist features, phase-shifted photomasks, other suitable techniques, or a combination thereof. In one embodiment, reverse lithography techniques that use optical proximity correction as a treatment for reverse imaging issues may also be used.

In one embodiment, after completing the design of the layout pattern of the photomask, the photomask manufacturer may form the photomask pattern on the photomask using electron beam (e-beam) or multiple electron beam mechanisms. In one embodiment, the photomask is formed using binary technology. In one embodiment, the photomask pattern includes an opaque region and a transparent region, which are subsequently used to mask or transmit the exposed radiation beam (e.g., an ultraviolet (UV) beam) to the layer of image-sensitive material (e.g., photoresist) that has been coated on the wafer. In one embodiment, the binary mask includes a transparent substrate (e.g., fused silica) and an opaque material (e.g., chromium) coated in the opaque region of the mask. In another embodiment, the photomask is formed by using a phase shift technique, and in a phase shift mask (PSM), various components in the pattern formed on the mask are configured to have an appropriate phase difference to enhance resolution and image quality. In various embodiments, the phase shift mask may be an attenuated phase shift mask or an alternating phase shift mask.

After generating the photomask pattern, the resulting photomask may be used in various processes. For example, the photomask may be used by the integrated circuit manufacturer/fabricator to perform an ion implantation process to form various doped regions in the semiconductor wafer, an etching process to form various etched regions in the semiconductor wafer, and/or other suitable processes.

The embodiment of the present disclosure partially modifying the layout pattern of the photomask that was originally designed in consideration of the optical proximity modification. This effectively improves the edge roughness of the subsequent photoresist layer after the exposure process (e.g., shifting and tilting of sidewall exposures that may be encountered with linear patterns), thereby maintaining the memory device yield and manufacturing progress goals.

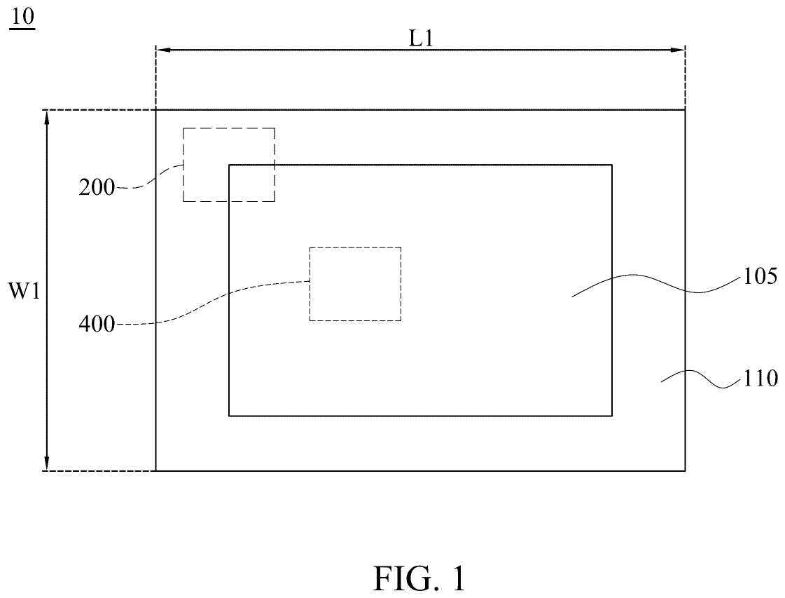

First, refer to FIG. 1. FIG. 1 illustrates a top view of the photomask pattern 10, in accordance with some embodiments of the present disclosure. The photomask pattern 10 includes a central region 105 and a peripheral region 110, and the peripheral region 110 surrounds the central region 105. In one embodiment, the length L1 of the photomask pattern 10 may be about 100 μm, the width W1 of the photomask pattern 10 may be about 100 μm, and the peripheral region 110 may be a region from about 1.5 μm to about 1.8 μm away from the boundary of the photomask pattern 10. In other words, the width of the peripheral region 110 may range from about 1.5 μm to about 1.8 μm. The dimension of the photomask pattern 10 may correspond to the dimension of the exposure shot for subsequent performing of the lithography process.

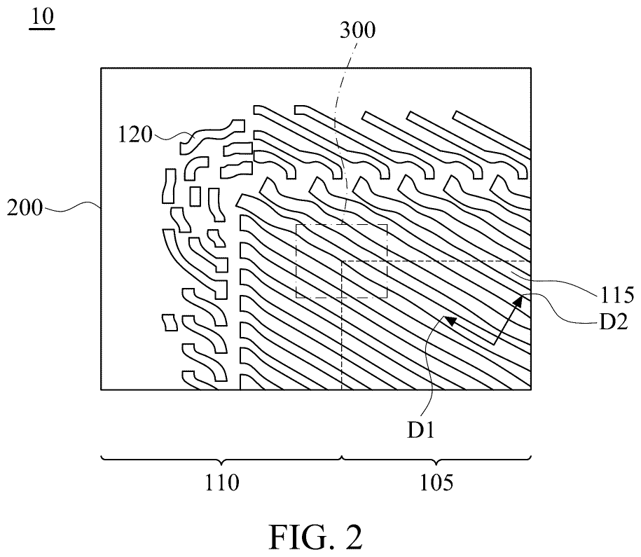

Next, refer to FIG. 2. FIG. 2 illustrates a fragmentary top view of the photomask pattern 10 in the region 200 of FIG. 1, in accordance with some embodiments of the present disclosure. The photomask pattern 10 includes a plurality of striped patterns 115. The striped patterns 115 are located in the central region 105 and the peripheral region 110. In one embodiment, the striped patterns 115 extend along a first direction D1 and are arranged in a second direction D2, and the first direction D1 intersects the second direction D2. In one embodiment, the photomask pattern 10 further includes a plurality of spacer patterns 120. The spacer patterns 120 are located in the peripheral region 110 and surround the striped patterns 115, and the spacer patterns 120 and the striped patterns 115 are separated from each other. The spacer patterns 120 may be used to make optical proximity corrections to the edge portion of the striped patterns 115. In one embodiment, the spacer patterns 120 may be separated from the striped patterns 115 by a distance of from about 15 nm to about 50 nm.

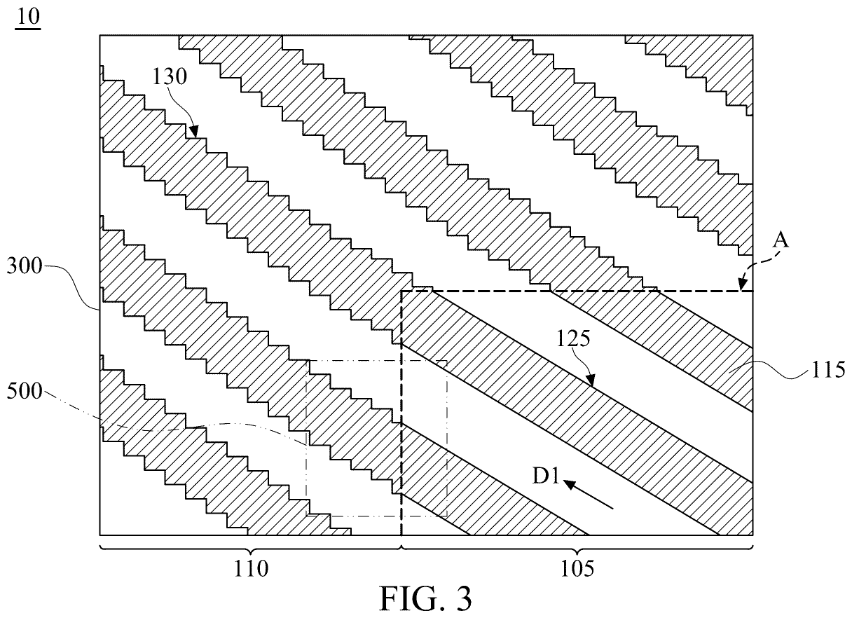

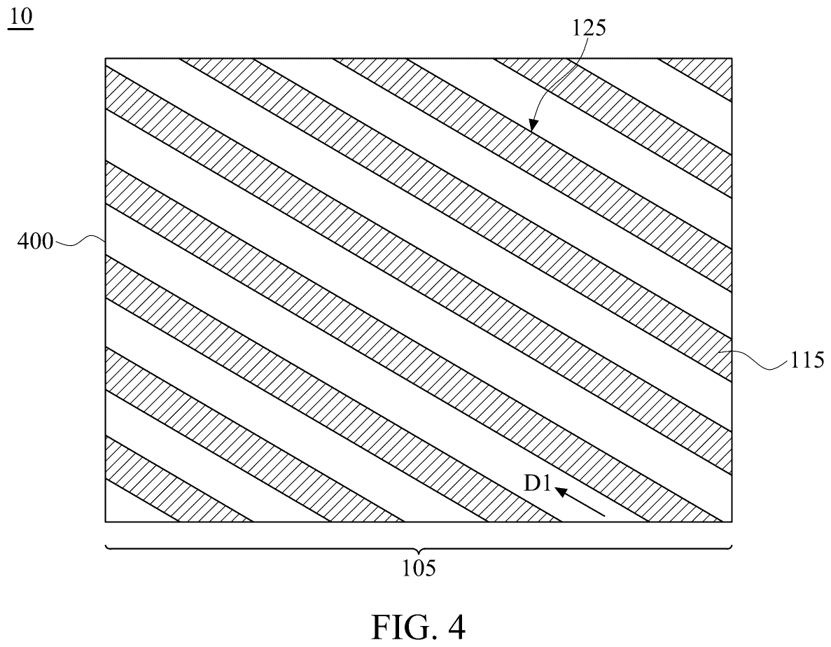

Refer to FIGS. 3 and 4. FIG. 3 illustrates a fragmentary top view of the photomask pattern 10 in the region 300 of FIG. 2, in accordance with some embodiments of the present disclosure. FIG. 4 illustrates a fragmentary top view of the photomask pattern 10 in the region 400 of FIG. 1, in accordance with some embodiments of the present disclosure. FIG. 3 further illustrates the detailed patterns of the striped patterns 115 at the intersection of the central region 105 and the peripheral region 110. FIG. 4 further illustrates the detailed patterns of the striped patterns 115 in the central region 105. In the conventional design of the layout pattern of the photomask, for the purpose of optical proximity correction, the sidewalls of the striped patterns 115 are usually designed to have stepped sidewalls 130. However, the embodiment of the present disclosure partially modifies the layout pattern of the photomask originally considered for the optical proximity correction. By modifying the portion of the striped patterns 115 located in the central region 105 to have straight sidewalls 125, the problem of edge roughness encountered during the exposure process of the photoresist layer on the wafer for the subsequently formed photomask may be effectively improved, thereby maintaining the goal of the memory device yield. For example, problems related to shifting and tilting of the sidewall exposure, which may be encountered with a linear photoresist pattern, have been improved. In addition, by only partially modifying the striped patterns 115 in the central region 105 to be straight sidewalls 125, rather than modifying the striped patterns 115 in the peripheral region 110 together to be straight sidewalls 125, the generation time of the photomask manufacturer for manufacturing the photomask with the photomask pattern 10 may be improved.

Still refer to FIGS. 3 and 4. In FIGS. 3 and 4, the sidewalls of each of the striped patterns 115 are straight sidewalls 125 in the central region 105 extending in the first direction D1. In FIG. 3, the sidewalls of each of the striped patterns 115 are stepped sidewalls 130 in the peripheral region 110 extending in the first direction D1. In one embodiment, each of the striped patterns 115 has stepped sidewalls 130 at two ends of each of the striped patterns 115. In one embodiment, the interface A between the central region 105 and the peripheral region 110 is the interface between the straight sidewalls 125 and the stepped sidewalls 130.

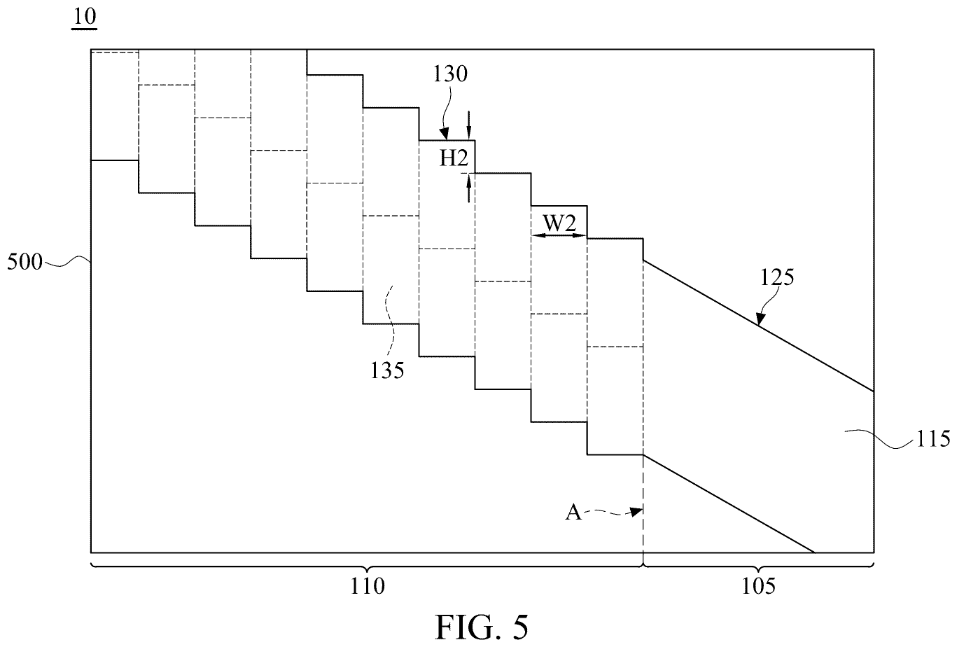

Refer to FIG. 5. FIG. 5 illustrates a fragmentary top view of the photomask pattern 10 in the region 500 of FIG. 3, in accordance with some embodiments of the present disclosure. In one embodiment, the stepped sidewalls 130 may have the same step width. In one embodiment, the stepped sidewalls 130 may have the same step height. In one embodiment, the stepped sidewalls 130 are formed by a plurality of rectangles 135 in the peripheral region 110. In one embodiment, each of the rectangles 135 has substantially the same area. In one embodiment, the step width W2 of the stepped sidewalls 130 may range from about 20 nm to about 30 nm. In one embodiment, the step height H2 of the stepped sidewalls 130 may range from about 10 nm to about 20 nm.

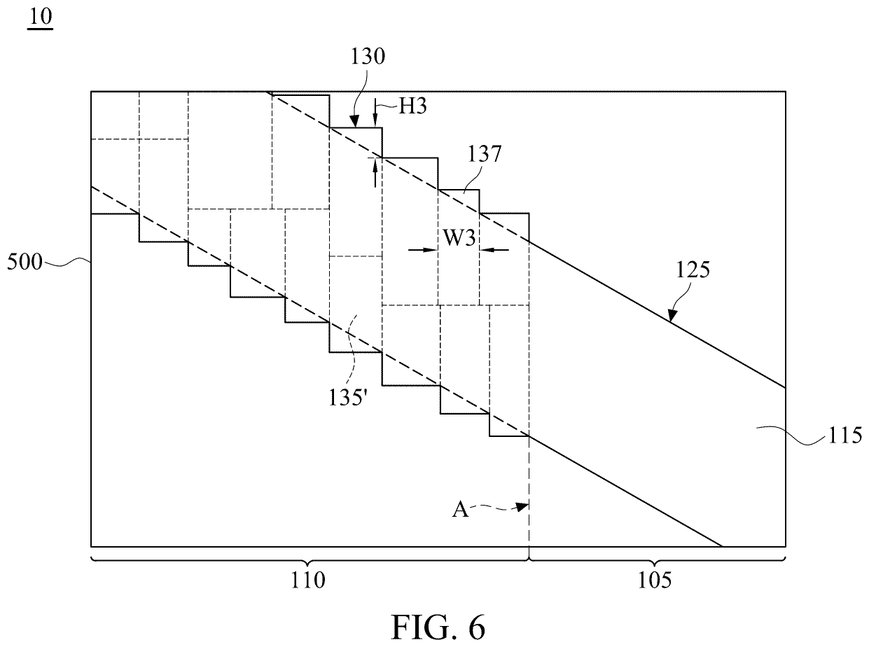

Refer to FIG. 6. FIG. 6 illustrates a fragmentary top view of the photomask pattern 10 in the region 500 of FIG. 3, in accordance with some other embodiments of the present disclosure. In the present embodiment, the stepped sidewalls 130 may have different step widths. In addition, the stepped sidewalls 130 may have different step heights. Further, the stepped sidewalls 130 are composed of a plurality of rectangles 135′ in the peripheral region 110, with each of the rectangles 135′ having a different area from each other. In addition, the boundaries of the rectangles 135′ and the extension lines of the sidewalls of the striped patterns 115 further form a plurality of triangles 137, and as the areas of the individual rectangles 135′ are different from each other, the areas of the individual triangles 137 are also different from each other. The step width W3 of the stepped sidewalls 130 may range from about 10 nm to about 15 nm. The step height H3 of the stepped sidewalls 130 may range from about 5 nm to about 10 nm.

In summary, compared to the conventional layout pattern design of the photomask, the embodiment of the present disclosure partially modifies the layout pattern of the photomask originally considered for optical proximity modification. This effectively improves the edge roughness of the subsequent photoresist layer after the exposure process (e.g., shifting and tilting of sidewall exposures that may be encountered with linear patterns), thereby maintaining the memory device yield and manufacturing progress goals. Thus, the various embodiments described herein offer several advantages over the existing art. It will be understood that not all advantages have been necessarily discussed herein, no particular advantage is required for all embodiments, and other embodiments may offer different advantages.

The foregoing outlines features of several embodiments of the present disclosure so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photomask pattern, comprising:
a central region;
a peripheral region surrounding the central region; and
a plurality of striped patterns disposed in the central region and the peripheral region, wherein the striped patterns extend in a first direction and are aligned in a second direction, and the first direction intersects the second direction,
wherein in a top view, sidewalls of each of the striped patterns further comprise a straight sidewall extending in the first direction in the central region,
wherein in the top view, the sidewalls of each of the striped patterns further comprise a stepped sidewall extending in the first direction in the peripheral region.

2. The photomask pattern as claimed in claim 1, wherein two ends of each of the striped patterns have the stepped sidewall.

3. The photomask pattern as claimed in claim 1, wherein an interface between the central region and the peripheral region is an interface between the straight sidewall and the stepped sidewall.

4. The photomask pattern as claimed in claim 1, wherein the stepped sidewall has a same step width.

5. The photomask pattern as claimed in claim 1, wherein the stepped sidewall has different step widths.

6. The photomask pattern as claimed in claim 1, wherein the stepped sidewall has a same step height.

7. The photomask pattern as claimed in claim 1, wherein the stepped sidewall has different step heights.

8. The photomask pattern as claimed in claim 1, wherein the stepped sidewall is formed by a plurality of rectangles in the peripheral region.

9. The photomask pattern as claimed in claim 8, wherein each of the rectangles has substantially a same area.

10. The photomask pattern as claimed in claim 8, wherein each of the rectangles has a different area.

11. The photomask pattern as claimed in claim 8, wherein a boundary of the rectangles further forms a plurality of triangles with an extension line of a sidewall of the striped patterns.

12. The photomask pattern as claimed in claim 11, wherein each of the rectangles has a different area, and wherein each of the triangles has a different area.

13. The photomask pattern as claimed in claim 1, further comprising:
a plurality of spacer patterns in the peripheral region and surrounding the striped patterns,
wherein the spacer patterns are separated from the striped patterns.

14. The photomask pattern as claimed in claim 13, wherein a distance between the spacer patterns and the striped patterns is from 15 nm to 50 nm.

15. The photomask pattern as claimed in claim 1, wherein a step width of the stepped sidewall is from 10 nm to 15 nm.

16. The photomask pattern as claimed in claim 1, wherein a step height of the stepped sidewall is from 5 nm to 10 nm.

17. The photomask pattern as claimed in claim 1, wherein a width of the peripheral region is from about 1.5 μm to about 1.8 μm.

18. The photomask pattern as claimed in claim 1, wherein a step width of the stepped sidewall is from 20 nm to 30 nm.

19. The photomask pattern as claimed in claim 1, wherein a step height of the stepped sidewall is from 10 nm to 20 nm.

20. The photomask pattern as claimed in claim 1, wherein the first direction is perpendicular to the second direction.
